(19) United States
(12) Patent Application Publication
(10) Pub. No.: US 2011/0306258 A1
(43) Pub. Date: Dec. 15, 2011

(54) FLAME RETARDATION OF TEXTILES BY HALOGENATED ARYL PHOSPHONATES

(76) Inventors: Royi Mazor, Beit-Kama (IL); Asher Shoshan, Beer-sheva (IL); Itzhak Shalev, Bet Gamliel (IL); Michael Peled, Beer-Sheva (IL)

(21) Appl. No.: 13/125,347

(22) PCT Filed: Oct. 22, 2009
(86) PCT No.: PCT/IL2009/000994

§ 371 Date: Aug. 10, 2011

Related U.S. Application Data
(60) Provisional application No. 61/107,709, filed on Oct. 23, 2008.

(51) Int. Cl. B32B 5/02; C09K 21/12; B05D 3/12; B05D 3/02; C23C 16/44; B05D 5/00; D06P 5/02; C08K 5/53

(52) U.S. Cl. 442/144; 8/490; 252/608; 524/132; 427/394; 427/255.6; 427/288; 427/373; 427/355

(57) ABSTRACT

The present invention discloses novel halogenated flame retardant formulations that effectively flame retard textiles at low binder and/or the flame retardant synergist contents, novel modes of application thereof on textiles, and flame-retarded textile fibers and fabrics which are treated by these formulations.

Textiles are an essential part of everyday life and are found, for example, in draperies, cloths, furniture and vehicle upholsteries, toys, packaging material and many more applications. Consequently, textile flammability is a serious industrial concern.

Flame retardants (FR) used for the protection of textiles must be environmentally and physiologically safe, compatible with the fabric, non-damaging to the aesthetical and textural properties of the fabric (for example, to remain transparent) and must be resistant to extensive washing and cleaning (generally termed as “durable”). Above all, a flame retardant agent suitable for textile treatment should pass the standard flammability tests in the field, preferably even after 5, 10 or 50 washing cycles.

Presently, there are four main families of flame-retardant chemicals used in various fields:

a) Inorganic flame retardants;

b) Halogenated flame retardants;

c) Organophosphorus flame retardants; and

d) Nitrogen-based organic flame retardants.

Of these, flame retardation of textiles is mostly conducted using aromatic bromine-containing formulations, which are adhered to the substrates by means of binders.

The main drawbacks of existing formulations include high bromine content demand, high dry add-on demand, streak marks on dark fabrics, excessive dripping during combustion of thermoplastic fibers and dispersion instability. For example, the percentage of resin component may be as high as 60-70% by weight of the total fabric weight (add-on) in order to obtain satisfactory flame retardation, usually due to the large amount of binder needed to fix the flame retardant agent(s) to the textile (the binder being as high as 50% by weight of the total FR formulation; see Toxicological Risks of Selected Flame-Retardant Chemicals (2000) page 507). Due to its substantial presence, the binder contributes to flammability and dripping, which requires the addition of even more bromine, thus creating an inefficient cycle. Often, the high add-on adversely affects otherwise desirable aesthetical and textural properties of the fabric. For example, upon application of a FR with a large amount of binder, fabrics may become stiff and harsh and may have duller shades, and poor tear strength and abrasion properties.

Antimony based compounds (such as antimony oxide, antimony pentoxide, tin hydroxyl stagnate and more) are often used as synergists with other flame retardants, thereby increasing the overall efficiency and reducing the amount of halogenated FR agents to be used. However, antimony based synergists are heavy, increase the weight of the fabric, require the addition of more binder, and are easily washed off during laundry (Touval, I., (1993) “Antimony and other inorganic Flame Retardants” in Kirk Othmer's Encyclopedia of Chemical Technology, Vol. 10, p. 936-954, 4^{th} Edition, John Wiley and Sons, N.Y.).

In order to obtain better flame retarded textiles, an efficient flame retardant is required that can be useful in low binder/FR synergist content and that would have good dispersion properties, on top of the other qualities discussed above.

It should be noted that other methods of contacting the FR and the fiber are known, for example through exhaustion.

The term “exhaustion” is used herein to describe the transfer of the FR from the emulsion, dispersion or suspension in which it is dispersed, to the fibers of the fabric immersed in this emulsion, dispersion or suspension, and subsequently drying this fabric. This term includes both complete and incomplete consumption of the emulsion or suspension.

The term “dispersion” as used herein means a two-phase system in which one phase generally consists of substantially finely-divided particles, which are typically distributed throughout a bulk substance, the particles being the “dispersed” phase and the bulk substance or carrier, being the “continuous” phase. Dispersions include, for example, liquid/liquid forms (emulsions) and solid/liquid forms (solutions, suspensions or colloidal dispersions).

Exhaustion is used with phosphorus-based FRs, such as Avocet™ products, for the treatment of polyester (http://www.avocet-dyes.co.uk/products.php?product_catagory_id=3).

Diethyl-2,3,4,5,6-pentabromobenzylphosphonate (DEPBBP or FRX 546) is an exemplary flame retardant having a combination of aromatic bromine and a phosphorus-containing functional group. The preparation of DEPBBP and structurally-related compounds is described in a provisional application No. 61/107,690, by the present assignee, co-filed on the same date as the instant application and entitled “A Process For The Preparation Of Dialkyl Halogenated Aryl Phosphonates”, which is incorporated by reference as if fully set forth herein.

It has now been found that DEPBBP and additional compounds having the general formula I, as outlined below:

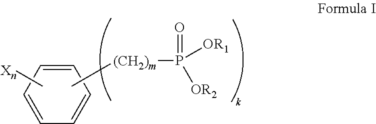

such that each X may independently represent a halogen (preferably chlorine (Cl) or bromine (Br), especially bromine); k is 1 or 2; n is an integer between 1 and 5, inclusive; m is an integer between 1 and 3, inclusive; and R₁ and R₂ are independently a straight or branched C₁-C₅ alkyl group which may be optionally substituted with one or more halogen atoms,

,can be processed to obtain a novel halogenated flame retardant formulation, which can then be applied on a variety of fabrics while exhibiting unexpected homogeneity and transparency, at a relatively low binder content and even without using any antimony-trioxide flame retardant synergist.

Such an FR formulation comprises a compound having the formula I as described hereinabove, and a carrier, and effectively flame retards a variety of fabrics, without damaging the aesthetical or textural properties of the fabric, maintaining these properties even after many washing cycles.

Different compounds having the general formula I have been prepared and found to effectively flame retard textiles, as described below.

One such compound is Diethyl-2,3,4,5,6-pentabromobenzylphosphonate (DEPBBP), which corresponds to formula I above when k=1, R₁═R₂═C₂H₅, m=1, n=5, and X is Bromine (Br). As can be seen from Examples 2-7 hereinbelow, formulations comprising DEPBBP particles effectively flame retarded a variety of fabrics, while maintaining the esthetical and textural properties of these fabrics.

Some additional exemplary compounds having the general formula I are α,α′-bis-(dibutoxyphosphinyl)tetrabromo m-xylene (k=2, R₁═R₂=butyl, m=1, n=4, and X=bromine) and α,α′-bis-(dibutoxyphosphinyl)tetrabromo p-xylene (k=2, R₁═R₂=butyl, m=1, n=4, and X=bromine) and α,α′-bis-(diethoxyphosphinyl)tetrabromo o-xylene (k=2, R₁═R₂═C₂H₅, m=1, n=5, and X=bromine).

Therefore, according to one aspect of the invention, there is provided a flame retardant formulation comprising an FR compound having the structure depicted in formula I, as it has been defined hereinabove, and a carrier.

It should be stressed that the FR compound can be either a solid (as the compound of Examples 1A and 1C) or a liquid (such as the compounds of Example 1B) at room temperature.

Preferably, the FR compound is such that it is capable of being melted during heating at fabric processing temperatures (preferably between 70° C. and 180° C.) or is liquid at these temperatures, such that the FR particles will penetrate and evenly distribute within the fabric at the processing temperatures.

When the compounds of formula I are solid at room temperature (such as DEPBBP), they are preferably grinded to a pre-determined size to provide particles having a size which is suitable to enable an effective flame retardation of the fibers. Generally, the particles would have to be smaller than 100 microns, more preferably equal to or smaller than 10 microns.

The carrier used in these formulations may be either solid or liquid, but is preferably liquid. Liquid carriers may comprise solvents, but the carrier is preferably an aqueous carrier. Further preferably, the aqueous carrier is water.

The flame retardant formulation described herein may further comprise at least one additive selected from the group consisting of a flame retardant synergist, a smoldering suppressant agent, a surface active agent, an antifoaming agent, a preservative, a stabilizing agent, a binding agent, a thickening agent, a wetting agent, a suspending agent, a pH buffer, an anti creasing agent, a sequestering agent, a detergent, a dye, a pigment and any mixture thereof.

Suitable fabrics to be successfully flame retarded by the formulations of the present invention include those composed of both synthetic and natural fibers.

The term “fiber” as used herein refers to a natural or synthetic filament capable of being spun into a yarn or made into a fabric.

The terms “fabric”, “textile” and “textile fabric” are used herein interchangeably to describe a sheet structure made from fibers.

Exemplary fabrics include fabrics composed of fibers such as: wool, silk, cotton, linen, hemp, ramie, jute, acetate, lyocell, acrylic, polyolefin, polyamide, polylactic acid, polyester, rayon, viscose, spandex, metallic composite, ceramic, glass, carbon or carbonized composite, and any combination thereof.

The formulations described herein may be applied onto the flammable textile fabric by contacting the fabric with the flame retardant formulation described herein and heating this flammable textile fabric, preferably to between 70° C. and 180° C., thereby flame retarding it.

Contacting the fabric with the FR formulations of the present invention may be effected by exhaustion, spreading, coating, padding, dipping, printing, foaming and/or spraying.

The most preferred application methods are coating, spraying, dipping, padding and exhaustion.

The term “coating” as used herein, refers to the process of producing a generally continuous film or layer of a FR over, under or on both sides of the fabric surfaces.

Dipping refers to the immersion of a textile into a processing liquid, typically used in connection with a padding process.

Padding may be achieved by passing the textile between squeeze rollers, the bottom of which carries the composition to be applied, or by passing the textile through a bath and subsequently through squeeze rollers, the squeeze rollers acting to remove the excess composition.

Spraying occurs when the textile substrate is passed beneath a row of spray nozzles that apply the composition to the surface of the textile.

Coating, spraying, dipping and padding are conventional methods of treating textiles whereby a dispersion (if the FR is solid at room temperature) or emulsion (if the FR is liquid at room temperature) of the flame retardant is prepared and then applied onto the fabric.

Therefore, according to a preferred embodiment of the present invention, the flame retardant formulation described herein further comprises a dispersing agent, a suspending agent or an emulsifying agent to help disperse or emulsify the flame retardant in the carrier.

Preferably, the carrier is an aqueous carrier and thus, according to another preferred embodiment of the present invention, the flame retardant formulation may be in a form of an aqueous dispersion. As shown in the Examples section below (see for example, Example 6), dispersions of the flame retardants of the present invention were found to be stable for at least 5 days under room temperature conditions.

A disadvantage of flame retardation by coating, spraying, dipping or padding is often the need to apply the protective coating in large amounts and/or add high amounts of binders to adhere the flame retardant to the fabric (commonly termed “high add-on”) in order to obtain the required flame-resistant characteristics. Often, such high add-on adversely affects otherwise desirable aesthetical and textural properties of the fabric. For example, upon application of a FR, fabrics may become stiff and harsh and may have duller shades and poor tear strength and abrasion properties. One way to overcome this disadvantage is to coat only the back surface of the fabric, a process commonly termed as “back-coating”, which is most suitable in the case of draperies, furniture upholstering garments and linen.

It has now been found out that the flame retardant formulations of the present invention may effectively flame retard cotton fabrics treated by coating or back-coating (see Examples 6 and 7 below), while using relatively small amounts of binder either with or without the addition of FR synergists

It has also been surprisingly found by the present inventors that flame retardation can be effected on textile fabric by using exhaustion (see Examples 2-5), resulting in even further advantages, as described below.

Textile fabrics most suitable for treatment by exhaustion are fabrics composed of hydrophobic fibers, such as polyester fibers.

Exhaustion may be effected by using any conventional machinery for treating textiles and garments with liquors, including dollies, winches, beam dyeing equipment, jets, package dyeing machinery, hank dyeing machinery, top dyeing equipment, side paddle dyeing machines, continuous dye ranges, thermosoling machines, washing and laundering equipment and dry cleaning machinery for batchwise treatments and including pad mangles, lick-rollers, spray units, continuous cloth washing units, back washing machines and solvent scouring machines for continuous and semi-continuous treatments.

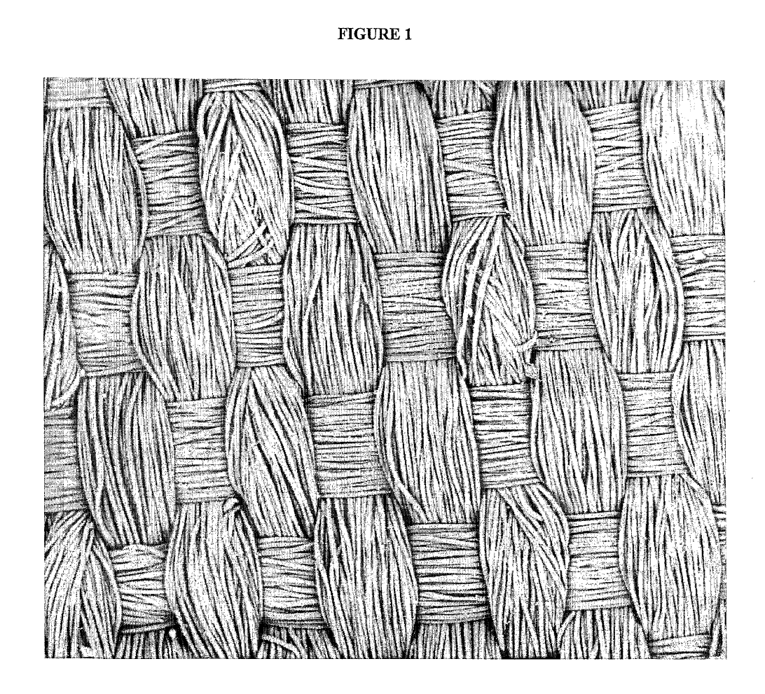

It has now been unexpectedly found that applying the flame retardant formulations of the present invention by exhaustion results in an effective flame retardation of the fabrics, while circumventing the need to use any binder since, without being bound to a specific theory, the flame retardant particles are incorporated into the fibers in the melt, and do not need a binder to adhere them to the fabric, as can be seen in FIGS. 1-3.

FIG. 1 presents a scanning electron microscopy (SEM) image of a polyester fabric treated by exhaustion in a Diethyl-2,3,4,5,6-pentabromobenzylphosphonate (DEPBBP) formulation, after curing, at ×100 magnification;

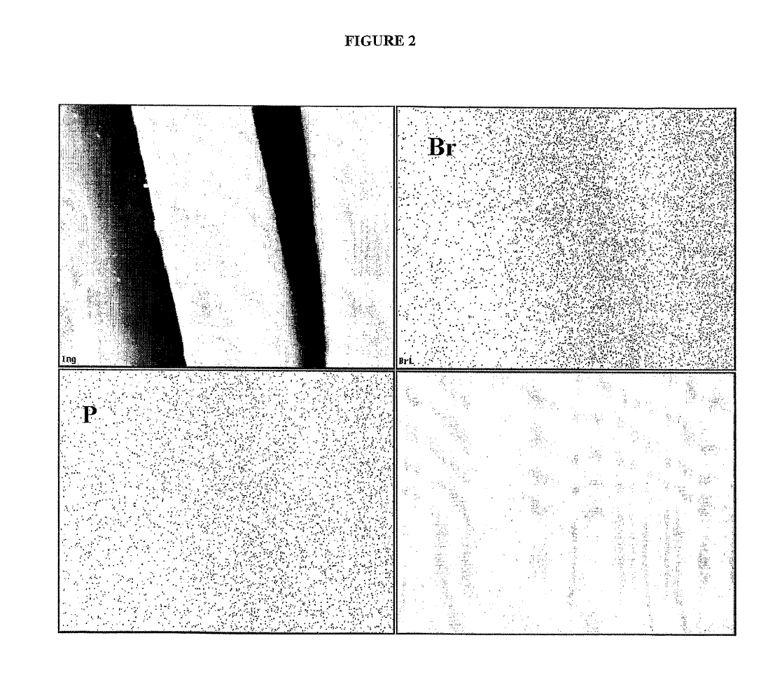

FIG. 2 presents an Energy Dispersive X-ray Spectra (EDS) of the surface displayed in FIG. 1, and

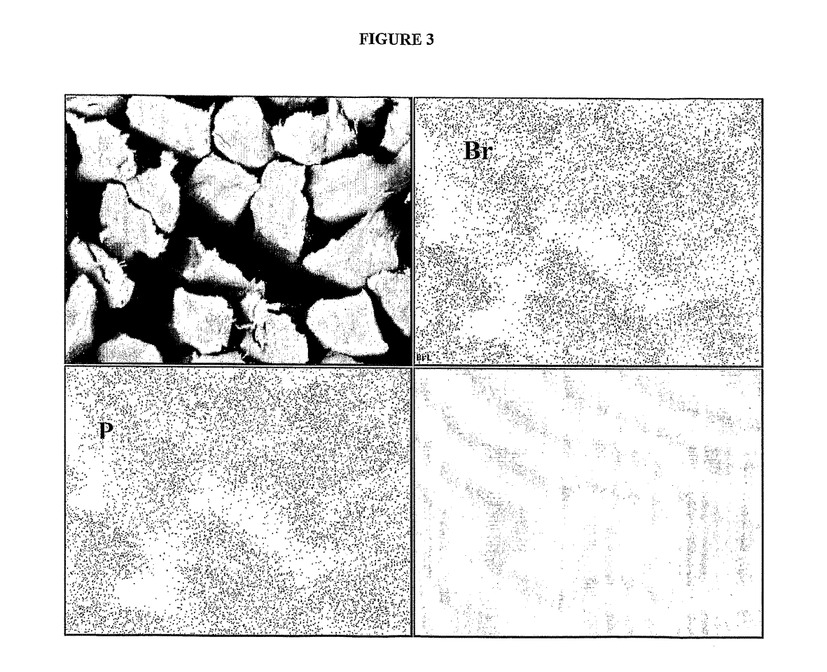

FIG. 3 presents an EDS Spectra of the cross-section of the polyester fibers displayed in FIG. 1.

Furthermore, using exhaustion to treat flammable fabrics also circumvents the need to use any flame retardant synergist, such as antimony-based compounds (although adding them is still possible) and therefore according to a preferred embodiment of the present invention, there are provided halogenated flame retardant formulations which are completely free of flame retardant synergists.

Optionally, the exhaustion may be conducted simultaneously with dyeing the fabric, by adding at least one dye during the exhaustion, for example into the dyeing machine. This presents an additional advantage in that flame retardation and dyeing can be effected in one step, lowering the costs of operation, and simplifying textile treatment.

As shown in the Examples section which follows, different textile fabrics were successfully flame retarded by a variety of application methods, when using the halogenated flame retardant formulations of the present invention.

Thus, according to another aspect of the invention, there is provided a flame retarded textile fabric, either coated or exhausted by a halogenated compound having the formula I described above.

These textile fabrics were found to have superior properties compared with the presently known FR-treated textile products.

In particular, the flame-retarded textile fabrics of the present invention are characterized by at least one aesthetical or textural property which is substantially the same as that of said textile fabric per se. The term “textile fabric per se” as used hereinafter, refers to a textile fabric which was not treated with a flame retardant formulation. Preferably, such an aesthetical or textural property is selected from the group consisting of flexibility, smoothness, streakiness, transparency and color vivacity.

Furthermore, it has now been found that the formulations of the present invention are suitable to treat both white fabrics and colored textile fabric, as in both cases there are no visible streak marks apparent on the treated fabric.

These properties are maintained even after extensive washings. Thus, according to a preferred embodiment of the present invention, the flame-retarded textile fabric described herein has a durability of at least 10 washing cycles.

These flame-retarded textile fabrics were characterized by an after flame time of less than 5 seconds, an after glow time of less than 10 seconds, and even less than 5 seconds, and a char length of less than 15 centimeters, wherein the after-flame time, the after-glow time and the char length are all defined by ASTM D-6413 12 seconds ignition test.

The flame-retarded textile fabrics described herein are further characterized by an add-on which is lower than 25% of the weight of the textile fabric per-se, and even by an add-on which is lower than 20% of the weight of the textile fabric per-se, ranges which are far lower than those common in the fabric flame retardation industry (often exceeding 30% and even 40% of the weight of the textile fabric per-se). For example, in coating experiments described below, the add-on was as low as 15.7% and moreover, in exhaustion experiments described below, the add-on was as low as 3.9%, and reflects the weight of the FR only on the fabric (no binder and no synergist in or on the fabric!).

As can be understood from the example above, in the case of fabrics treated by exhaustion, it was possible to obtain the excellent flame retardancy results even without using any FR synergist, such as ATO.

Therefore, according to a preferred embodiment of the present invention, there is provided a halogenated flame-retarded textile fabric which is free of antimony oxide.

Furthermore, in exhaustion applications, there was also no need to add any binder, since the exhaustion process introduces the FR particles into the fibers in the melt, as is clearly shown in FIGS. 1-3.

Thus, according to another preferred embodiment of the present invention, there is provided a halogenated flame-retarded textile fabric which is free of a binding agent.

In particular, as noted hereinabove, the fibers which are most suitable to be treated by exhaustion are hydrophobic fibers, and more specifically polyester fibers.

Given the binder-free and ATO-free nature of the fabrics treated by exhaustion, there is now provided, according to yet an additional aspect of the invention, a halogenated flame retarded polyester fiber being free of a binding agent and/or free of a flame retardant synergist, such as antimony oxide.

Preferably this fiber is flame retarded by compounds having the structure of Formula I, as they have been described hereinabove. More preferably, the compound of Formula I is Diethyl-2,3,4,5,6-pentabromobenzylphosphonate (DEPBBP).

According to another aspect of the invention, fabrics composed of these halogenated flame retarded polyester fibers, are also provided.

Additional objects, advantages, and novel features of the present invention will become apparent to one ordinarily skilled in the art upon examination of the following examples, which are not intended to be limiting. Additionally, each of the various embodiments and aspects of the present invention as delineated hereinabove and as claimed in the claims section below finds experimental support in the following examples.

### EXAMPLES

Reference is now made to the following examples, which together with the above descriptions, illustrate the invention in a non limiting fashion.

Throughout the examples, the terms “polyester fabric”, “cotton fabric” etc. refer to fabrics composed of polyester fibers, cotton fibers, respectively.

### Materials and Analytical Methods

Materials:

Tergitol™ 15-S-12, a non-ionic surfactant/dispersing agent, was obtained from Dow.

Terasil Yellow 4G dye was obtained from Huntsman.

Serilene Red 2BL dye and Serilene Blue RL dye were obtained from Yorkshire.

Instrumental Data:

Mixing was conducted using an IKEA lab mixer.

Exhaustion and/or dyeing were conducted either on an industrial mini jet pilot batch dyeing machine (Thies Mini Jet) having a 5 Kg fabric capacity and an 80 liters liquid capacity (liquor ratio: 1:16) or on a Mathis Labomat® laboratory dyeing machine, equipped with an AREL APC controller.

Fabric Characterization Methods:

Scanning electron microscope (SEM) equipped with an energy dispersive x-ray spectrometer (EDS; hereinafter SEM/EDS) was performed on a JEOL JSM-7400F ultrahigh resolution cold FEG-SEM. In this method a piece of fabric is coated with 10 nanometer of gold layer.

The percentage of bromine on the fabric was determined by adding tetrahydrofuran (THF) and extracting the coating from fabric specimens weighing 0.5 grams each. Each specimen is reacted with a sodium biphenyl complex reagent, to produce NaBr in an amount equivalent to the amount of bromine in the sample. The access reagent is treated with isopropanol and acidified with acetic acid. Finally, the amount of bromine is determined using a titration with AgNO₃.

The percentage of additives on the fabric (“Add-on”) was determined by the difference between sample weight before and after application of the FR formulation (deviation of ±1%).

Flammability Tests:

ASTM D-6413 12 seconds ignition test: In this method, samples are cut from the fabric to be tested, and are mounted on a frame that hangs vertically from inside the flame chamber. The sample is exposed to a controlled flame for a specified period of time (in this case for 12 seconds, one of the strictest flammability tests), and the “after-flame time” and the “after-glow time” are both recorded. Finally, the sample is torn by use of weights and the char length is measured. To pass, the average char length of five samples cannot exceed 7 inches (17.8 cm). In addition, none of the individual specimens can have a char length of 10 inches (25.4 cm).

Fabrics are tested in both directions (warp and fill) i.e. 5 samples are cut along the length and 5 samples are tested along their width.

Washing Fastness Tests:

Samples treated with the flame retardant formulations described herein were subjected to successive washing cycles in accordance with the washing procedure set forth below, followed by one drying cycle in accordance with commonly used drying procedure, based on the Standard Laboratory Practice for Home Laundering (AATCC technical manual/2001), unless otherwise noted.

In all washing cycles, the temperature of the washing water is maintained between 58° C. and 62° C. (unless noted otherwise), for automatic washing machines, the washing cycle is set for normal washing cycle, and a synthetic detergent that conforms to Standard Laboratory Practice for Home Laundering (AATCC technical manual/2001) is used.

### Example 1A

### Preparation of Diethyl-2,3,4,5,6-pentabromobenzylphosphonate (DEPBBP)

Into a 500 ml round bottomed flask equipped with mechanical stirrer, nitrogen inlet, and a pipe to a cooled (under ice) trap, were placed pentabromobenzyl bromide (PBB-Br, FR-706, R.H., 330 grams, 0.58 mol) and triethylphosphite (slight excess, 110 ml, 105 grams, 0.63 mol).

The mixture was gradually heated. The temperature was raised from 25° C. up to 100° C. over 50 minutes. During this period of time, PBB-Br completely dissolved in the hot triethylphosphite and the solution became yellowish. Ethylbromide started to evolve at 95° C. The temperature of the heating oil was kept at 100° C. during all the reaction time. An exothermic behavior is observed. The temperature rose spontaneously in the reaction vessel to 105° C. The temperature then increased to 110° C. and the reflux become stronger till 136° C. The temperature then dropped to 117° C. At this point the temperature of the heating plate was raised to 150° C. The temperature was maintained at 150° C. for one hour. At 150° C. a vacuum pump was applied in order to distill the residue of ethylbromide and the slight excess of triethylphosphite. The distillate (52 grams of ethylbromide) was trapped in the cold trap. The reaction mixture was spread as a molten product on aluminum foil. The molten product cooled to room temperature and flakes were achieved. The flaked FRX1145 was an off-white color, 360 grams, 0.578 moles, 99% yield. The flake was milled and a white powder was obtained.

Alternatively, DEPBBP can be prepared according to the process described in GB 2,228,939 by reacting pentabromobenzyl bromide and triethyl phosphite in o-xylene as a solvent. The product, which is isolated from the reaction mixture by filtration, is reported therein to have a melting point of 123-124° C.

### Example 1B

### Preparation of a mixture of α,α′-bis-(dibutoxyphosphinyl)tetrabromo m-xylene and α,α′-bis-(dibutoxyphosphinyl)tetrabromo p-xylene

Into a 250 ml round bottomed flask equipped with mechanical stirrer, nitrogen inlet, dropping funnel and an outlet pipe into a cooled trap(under ice), was placed a mixture of meta and para tetrabromoxylene dibromide (80 grams, 0.138 mol; abbreviated hereinafter TBXDB) and tributylphosphite (70 grams, 0.279 mol 1% molar excess). The amount of tributylphosphite was divided into two portions. The first portion, (35 grams 0.139 mole) was added into the reaction vessel together with TBXDB. The mixture which is a slurry of TBXDB in tributylphosphite, was gradually heated. The temperature was raised from 25° C. up to 105° C. over 60 min with an oil bath. An exothermic behavior is observed with strong reflux at this point. The temperature rose spontaneously in the reaction vessel to 134° C. TBXDB was completely dissolved at this temperature in tributylphosphite and the solution became brownish. When the temperature spontaneously decreased to 105° C., after 10-15 minutes, the second portion of tributylphosphite was added drop wise into the reaction vessel over a period of 20-30 minutes. During the second addition stage the temperature rose spontaneously in the reaction vessel to 116° C. with gentle reflux. When the addition of the second portion of tributylphosphite was completed, the oil bath was heated to 150° C. The temperature was maintained at 150° C. for one hour. The outlet pipe was replaced by a Dean-Stark trap and at 150° C., butylbromide and the slight excess of tributylphosphite were removed by vacuum distillation. The reaction mixture was spread on an aluminum foil. Although the product was cooled to room temperature, no solidification occurred and the product remained a liquid. The liquid was brownish colored, (94 grams, 0.117 mole, 85% yield). Elemental analysis calculated for C₂₄H₄₀Br₄O₆P₂: % Br 39.7, % P 7.7; found: % Br 38.8, % P 7.6.

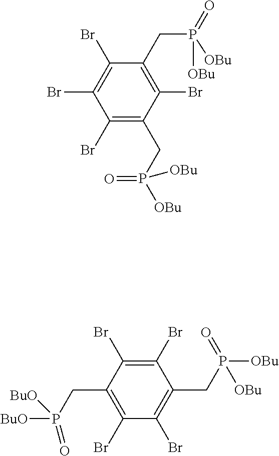

### Example 1C

### Preparation of α,α′-bis-(diethoxyphosphinyl)tetrabromo o-xylene

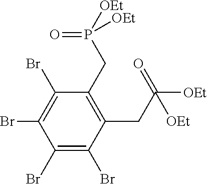

Ortho-tetrabromoxylene dibromide (10 grams, 0.01725 mole) and triethylphosphite (5.8 grams, 0.035 mole) were reacted according to the procedure described in Example 1B. Having completed the reaction, the reaction mass was spread on an aluminum foil. The entitled product, which was allowed to cool to room temperature, solidified. The flakes collected (10.7 grams) had off-white color. The flakes were milled and a white powder was obtained. The melting point was determined by DSC (melt onset 127.9° C., peak temperature 133.5° C.). Elemental analysis calculated for C₁₆H₂₄Br₄O₆P₂: % Br 46.1, % P 8.9; found: % Br 47.9, % P 8.3.

### Example 2

### General Protocol: Exhaustion and Dyeing of DEPBBP on Polyester Fabric

A dyeing machine is filled with soft water and fabric is loaded. The machine is pre-heated to 60° C. to help uniform mixing with the DEPBBP thereafter. DEPBBP is grinded using a mortar and pestle and is then added to the dyeing machine. Any additional chemicals and dyes are placed at this stage into the additions tank. Heating is conducted to 130° C. for 30 minutes, followed by 30 additional minutes at 80° C. for. The bath is removed and the fabric is washed in warm soap (Avcopal nonionic surfactant) at 60° C., cold rinsed and removed from the dyeing machine.

### Example 3

### Exhaustion with DEPBBP of a White Polyester Fabric, Combined with Dyeing

Previously grinded DEPBBP (528 grams, equivalent to 10.5% by weight of fabric), was applied by exhaustion to a 100% white polyester 1×1 rib knit fabric weighing 200 grams/m², according to the procedure disclosed in Example 2, also adding acetic acid (150 grams), an anti creasing agent (proprietary, 150 grams), a sequestering agent (proprietary, 38 grams) and a detergent (proprietary, 7.5 grams).

The fabric was simultaneously dyed to a medium gray shade using a combination of commercial dispersion dyes (0.013% Terasil Yellow 4G, 0.025% Serilene Red 2BL and 0.058% Serilene Blue RL.

The fabric was removed and samples were laundered five times and ten times according to AATCC Standard Practice for Home Laundry at 60° C. Examination of a sample taken from the exhaustion bath showed a small quantity of white crystals precipitating at the bottom of the container. Qualitative analysis identified the white crystals as comprising of 99% DEPBBP.

The treated and washed fabric was evenly dyed and remained soft and smooth. No blotching, streaking or white marks were observed. No residue was observed on the dyeing machine.

The dry add-on, DEPBBP content, bromine (Br) content, phosphorus (P) content and flammability results of the treated fabric (after 5 and 10 laundry cycles, according to ASTM D6413-99, 12 seconds ignition) were measured and compared to the flammability results of the un-treated fabric (after 1 laundry cycle at 95° C., according to ASTM D6413-99, 12 seconds ignition), and are shown in Table 1 below.

TABLE 1

| | | | | | | flammability test | | | |
|---|---|---|---|---|---|---|---|---|---|
| | | | | | | After | After | Char | |
| | % Add- | % | % | | Laundry | flame | Glow | Length | |
| Fabric Tested | on | FR | Br | % P | cycles | seconds | seconds | cm | comments |
| Untreated | — | — | — | — | 1* | 27 (L) | — | 18 (L) | severe |
| | | | | | | 17 (W) | — | 10 (W) | flaming |
| | | | | | | | | | dripping |
| Treated | 3.90 | 3.85 | 2.46 | 0.20 | 5 | 8 (L) | — | 10 (L) | little |
| | | | | | | 9 (W) | — | 8 (W) | dripping |
| Treated | 3.90 | 3.85 | 2.46 | 0.20 | 10 | 3 (L) | — | 12 (L) | little |
| | | | | | | 2 (W) | — | 7 (W) | dripping |

*at 95° C.,
L = length direction,
W = width direction.

### Example 4

### Exhaustion with DEPBBP of a White Greige Polyester Fabric, With/Without Dyeing

A sample of greige 100% polyester fabric (17.5 grams) was placed in the beaker which was then sealed and exhausted according to the procedure of Example 2 using the pre-grinded DEPBBP (1.5 grams). The fabric was removed and laundered five times according to AATCC Standard Practice for Home Laundry at 60° C. The treated and washed sample was visually unchanged compared to the greige fabric.

The process above was repeated with the addition of Terasil® Blue 3RL dye (0.7 grams) to the beaker to obtain a fabric dyed with a medium shade of brilliant blue. The sample was removed and laundered five times according to AATCC Standard Practice for Home Laundry at 60° C.

### Example 5

### Exhaustion with DEPBBP of a Colored Polyester Fabric

A bluish 100% polyester woven fabric weighing 183 grams/m² (about 7 grams) was inserted in a reaction vessel together with pre-grinded DEPBBP (about 0.7 grams)) and de-ionized water (50 ml) and exhausted as described in Example 2. The fabric composition, before laundry, is described in Table 2 below:

TABLE 2

| Component | wt % |
|---|---|
| Dry solids | 15.4 |
| DEPBBP | 15.4 |
| Br | 9.8 |
| P | 0.8 |

The treated fabrics were laundered twice according to AATCC 60° C. home laundry protocol.

The tested fabrics appeared soft and smooth with no visible traces of a surface finish. The bluish color of the polyester fabric was undamaged by applying the DEPBBP flame-retardant thereon.

Flame retardancy testing, according to ASTM D6413-99 vertical 12 seconds ignition test, resulted in an after flame of 0 seconds, an after glow of 0 seconds and a char length of 11 cm.

The polyester fabrics were also submitted to SEM analysis for determination of the penetration of the DEPBBP and EDAX analysis to evaluate distribution uniformity of Br and P on the fibers. The results are presented in FIGS. 1-3. These figures demonstrate the penetration of DEPBBP into the polyester fabric after laundry. The SEM micrograph (FIG. 1) shows good penetration into the polyester fibers with no significant crystallization on the fiber surfaces indicating considerable affinity to polyester above its Tg. EDAX mapping analysis shows excellent uniformity penetration of both Br and P in the polyester fibers (FIG. 2) and to the fibers core (FIG. 3).

### Example 6

### A Coating Application of DEPBBP on a white 100% Knitted Cotton Fabric

Ground DEPBBP (258 grams) was dispersed in soft water and (1 liter) using Tergitol™ 15-S-12 surfactant (2 grams), to obtain a stable dispersion, later used in to coat fabrics. The composition of this dispersion is described in Table 3 below:

TABLE 3

| Component | wt % |
|---|---|
| Dry solids | 26 |
| DEPBBP | 25.8 |
| Br | 16.5 |
| P | 1.3 |

100% cotton knit 200 grams/m² fabric was padded with this dispersion, dried and cured at 160° C. The fabric composition, before laundry, is described in Table 4 below:

TABLE 4

| Composition | wt % |
|---|---|
| Add-on | 15.7 |
| DEPBBP | 15.6 |
| Br | 10.0 |
| P | 0.8 |

The treated fabrics were laundered twice according to AATCC 60° C. home laundry protocol and appeared soft and smooth with no visible traces of a surface finish. Flame retardancy testing, according to ASTM D6413-99 vertical 12 seconds ignition test, resulted in an after flame of 0 seconds, an after glow of 3 seconds and a char length of 12 cm.

### Example 7

### A Back Coating Application of DEPBBP on a blue 50% Cotton 50% Polyester Woven Fabric

Ground DEPBBP (128 grams) was dispersed in soft water (244 cc) further adding Tergitol™ 15-S-12 surfactant (2.5 grams), 49 grams of antimony trioxide, 44 grams of an acrylic latex binder and 1.5 grams of an acrylic acid thickener to obtain a stable dispersion. The composition of this dispersion is described in Table 5 below:

TABLE 5

| Component | wt % |
|---|---|
| Dry solids | 54 |
| DEPBBP | 27.3 |
| Br | 17.4 |
| P | 1.4 |

A 50% cotton/50% Polyester woven fabric 200 grams/m² fabric was knife back-coated with this dispersion, dried and cured at 160° C. The fabric composition is described in Table 6 below:

TABLE 6

| Composition | wt % |
|---|---|
| Add-on | 21.8 |
| DEPBBP | 10.7 |
| Br | 6.8 |
| P | 0.6 |

Flame retardancy testing, according to ASTM D6413-99 vertical 12 seconds ignition test, resulted in an after flame of 0 seconds, an after glow of 8 seconds and a char length of 16 cm.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

1. A halogenated flame retardant formulation comprising a carrier and a compound having the formula I 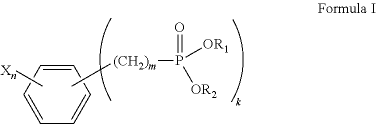
wherein each of R₁ and R₂ is independently a straight or branched C₁-C₅ alkyl group,
further wherein each X independently represents a halogen; k is 1 or 2; n is an integer between 1 and 5, inclusive; and m is an integer between 1 and 3, inclusive.

2. The flame retardant formulation of claim 1, wherein X is selected from the group consisting of chlorine and bromine.

3. The flame retardant formulation of claim 1, wherein the compound of Formula I is diethyl-2,3,4,5,6-pentabromobenzylphosphonate (DEPBBP).

4. The flame retardant formulation of claim 1, further comprising a dispersing agent, a suspending agent or an emulsifying agent.

5. The flame retardant formulation of claim 1, wherein said carrier is an aqueous carrier.

6. The flame retardant formulation of claim 5, being in a form of an aqueous dispersion.

7. The flame retardant formulation of claim 6 being stable for at least 5 days at room temperature.

8. The flame retardant formulation of claim 1, further comprising one or more additives selected from the group consisting of a flame retardant synergist, a smoldering suppressant agent, a surface active agent, an antifoaming agent, a preservative, a stabilizing agent, a binding agent, a thickening agent, a wetting agent, a suspending agent, a pH buffer, an anti creasing agent, a sequestering agent, a detergent, a dye, a pigment and any mixture thereof.

9. The flame retardant formulation of claim 1 being free of a flame retardant synergist.

10. A flame retarded textile fabric, coated or exhausted by a halogenated compound having the formula I: 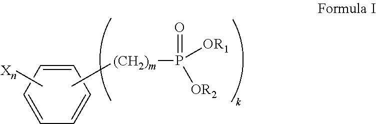
wherein each of R₁ and R2 is independently a straight or branched C₁-C₅ alkyl group,
further wherein each X may independently represent a halogen; k is 1 or 2; n is an integer between 1 and 5, inclusive; m is an integer between 1 and 3, inclusive.

11. The flame-retarded textile fabric of claim 10, wherein the compound of Formula I is diethyl-2,3,4,5,6-pentabromobenzylphosphonate (DEPBBP).

12. The flame-retarded textile fabric of claim 9, wherein said fabric is composed of a fiber selected from: wool, silk, cotton, linen, hemp, ramie, jute, acetate, lyocell, acrylic, polyolefin, polyamide, polylactic acid, polyester, rayon, viscose, spandex, metallic composite, ceramic, glass, carbon or carbonized composite, and any combination thereof.

13. The flame-retarded textile fabric of claim 9, being characterized by at least one aesthetical or textural property which is substantially the same as that of said textile fabric per se.

14. The flame-retarded textile fabric of claim 9, being a colored textile fabric.

15. The flame-retarded textile fabric of claim 9, having a durability of at least 10 washing cycles.

16. The flame-retarded textile fabric of claim 9, characterized by an after flame time, as defined by ASTM D-6413 12 seconds ignition test, of less than 5 seconds.

17. The flame-retarded textile fabric of claim 9, characterized by an after glow time, as defined by ASTM D-6413 12 seconds ignition test, of less than 10 seconds.

18. The flame-retarded textile fabric of claim 17, characterized by an after glow time, as defined by ASTM D-6413 12 seconds ignition test, of less than 5 seconds.

19. The flame-retarded textile fabric of claim 9, characterized by a char length, as defined by ASTM D-6413 12 seconds ignition test, of less than 15 centimeters.

20. The flame-retarded textile fabric of claim 9 being free of a flame retardant synergist.

21. The flame-retarded textile fabric of claim 9 being free of a binding agent.

22. The flame-retarded textile fabric of claim 9, characterized by an add-on which is lower than 25% of the weight of the textile fabric per-se.

23. The flame-retarded textile fabric of claim 22, characterized by an add-on which is lower than 20% of the weight of the textile fabric per-se.

24. A halogenated flame retarded polyester fiber being free of a binding agent and/or free of a flame retardant synergist.

25. The polyester fiber of claim 24, flame retarded by a halogenated compound having the formula I: 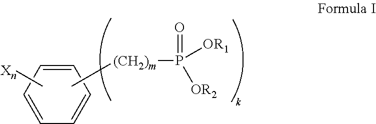
wherein each of R₁ and R₂ is independently a straight or branched C₁-C₅ alkyl group,
further wherein each X may independently represent a halogen; k is 1 or 2; n is an integer between 1 and 5, inclusive; m is an integer between 1 and 3, inclusive.

26. The polyester fiber of claim 25, wherein the compound of Formula I is diethyl-2,3,4,5,6-pentabromobenzylphosphonate (DEPBBP).

27. A fabric composed of the polyester fiber of claim 24.

28. A process of applying the flame retardant formulation of claim 1 onto a flammable textile fabric, the process comprising:
Contacting the flammable textile fabric with the flame retardant formulation; and
heating said flammable textile fabric, thereby obtaining a flame retarded textile fabric.

29. The process of claim 28, wherein said heating is conducted at between 70° C. and 180° C.

30. The process of claim 28, wherein said contacting is effected by exhaustion, spreading, coating, padding, dipping, printing, foaming and/or spraying.

31. The process of claim 30, wherein said contacting is effected by exhaustion.

32. The process of claim 31, wherein said fabric is composed of polyester fibers.

33. The process of claim 31, further comprising simultaneously dyeing said fabric by adding at least one dye during said exhaustion.
